(19) United States
(12) Patent Application Publication
(10) Pub. No.: US 2017/0155360 A1
(43) Pub. Date: Jun. 1, 2017

(54) SOLAR MODULE

(71) Applicant: SOLARWORLD INNOVATIONS GMBH, Freiberg (DE)

(72) Inventors: Harald HAHN, Dresden (DE); Holger NEUHAUS, Freiberg (DE); Martin KUTZER, Penig (DE)

(73) Assignee: SOLARWORLD INNOVATIONS GMBH, Freiberg (DE)

(21) Appl. No.: 15/364,988

(22) Filed: Nov. 30, 2016

(30) Foreign Application Priority Data
Nov. 30, 2015 (DE) 202015008287.4

(51) Int. Cl. H02S 40/44; H01L 31/052; H01L 31/054; H01L 31/0475; H01L 31/048

(52) U.S. Cl. CPC H02S 40/44; H01L 31/0475; H01L 31/048; H01L 31/0547; H01L 31/0521

(57) ABSTRACT

A Solar module, particularly hybrid photovoltaic solar hot water module, having at least two adjoining solar cells, which are configured at least partially bifacial and are embedded into a transparent laminate, wherein the laminate has a laminate rear-side on which a structure for guiding a heat transfer medium is provided, wherein a first section of the structure facing the laminate rear-side has a reflecting surface and is disposed to reflect the incidental light on the solar module, which does not directly strike the solar cells.

### FIELD OF INVENTION

The present invention relates to a solar module, particularly a hybrid photovoltaic solar hot water module.

### TECHNICAL BACKGROUND

Solar modules are used for converting solar radiation into energy. There are solar modules in the form of the so-called photovoltaic modules and in the form of the so-called solar hot water modules.

A photovoltaic module contains solar cells, which convert light into useful electrical energy.

A solar hot water module contains a so-called solar hot water collector, i.e. a region absorbing the solar radiation, which is configured to transfer the absorbed that is energy converted into heat to a heat transfer medium.

In addition, there are also hybrid photovoltaic solar hot water modules, the so-called hybrid PV/T or PVT modules. These usually have solar cells as well as a solar hot water collector. Therefore, this type of solar module is suitable for converting solar radiation into useful electrical energy and into useful thermal energy. Such a hybrid module is described for example in the document DE 10 2007 022 164 A1.

Sometimes, such hybrid modules have but only a comparatively low electrical area output.

### SUMMARY OF THE INVENTION

In the light of the above, the idea underlying the present invention is to specify an improved solar module.

In accordance with the invention, this object is achieved by a solar module with the features of claim 1 for protection.

Accordingly, a solar module, particularly a hybrid photovoltaic solar hot water module is provided, having at least two adjoining solar cells, which are configured at least partially bifacial and are embedded into a transparent laminate, wherein the laminate has a laminate rear-side on which a structure for conducting a heat transfer medium is provided, wherein a first section of the structure facing the laminate rear-side has a reflecting surface and is disposed to reflect the incidental light on the solar module, which does not directly strike the solar cells.

The knowledge underlying the present invention is that the cost-effectiveness of a hybrid photovoltaic solar hot water module can be improved considerably, if a preference is given to the demands on a high efficiency of the solar cells during the design of the solar module with respect to the requirements of the efficiency of the solar hot water collector. This is particularly achieved by using the solar module in a low-temperature domestic supply system, in which a heat transfer medium with comparatively low temperatures is used and thus is in a temperature range compatible with the solar cells in the operation.

Now, the idea underlying the invention is to use transparent embedded, at least partially bifacial solar cells in a hybrid module and to use the structure as a reflector, which is provided for conducting the heat transfer medium.

Solar cells are referred to as bifacial solar cells, in which the front-side as well as the rear-side can be used for generating power. Completely bifacial solar cells or even only partially bifacial solar cells can be used as at least partially bifacial solar cells. Preferably, it includes a so-called edge bifacial solar cells, which are configured bifacial only at the edge.

The increased efficiency of such at least partially bifacial solar cells is optimally utilized in a hybrid module according to the invention, since the structure conducting the heat transfer medium is configured with a reflecting surface at least in a first section. Thus, more useful light strikes on the solar cells, particularly on the rear-side thereof, for generating more electrical energy. Advantageously, no additional component is necessary for this purpose. Therefore, furthermore sufficient heat results, particularly in the form of waste heat of the solar cells, which can be used as solar thermal power.

Preferably, the reflecting surface has a reflection factor, also known as Albedo, of at least 50%, preferably at least 80%. Values of more than 90% would also be possible.

Overall, the structure conducting the heat transfer medium, thus has additional functions of a transfer structure or module rear wall optimally supporting a bifacial solar cell arrangement according to the invention. For this purpose, fastening point can also be provided for implementing the function of a supporting rail (Back rail).

In addition, the structure can fulfil a mechanical supporting function for the solar module. For example, thus the frame of the solar module can be advantageously dimensioned smaller or eliminated.

The structure conducting the heat transfer medium by corresponding thermal coupling can be used for cooling the solar cells. Therefore, the heat transfer medium is used for removing the waste heat of the solar cells in accordance with the invention, which can be operated in an efficient temperature range thereby. Therefore, the waste heat of the solar cells can advantageously be made useful. In particular, the temperatures of the heat transfer medium obtainable thereby, are suitable for the operation of low-temperature domestic supply systems.

The high output of the electric energy in accordance with the invention can be used, for example, for operating a heat pump of a (low-temperature) domestic supply system and/or for conveying the heat transfer medium. Therefore, the solar thermal component of the PVT-module can directly be used as a source for a low-temperature storage and/or the heat pump.

A variety of heat transfer fluids usable as heat transfer medium are suitable for heat-exchange applications, particularly for domestic supply systems.

Furthermore, it would be possible to use the structure conducting the heat transfer medium only for cooling, if necessary, to provide even without the use of the waste heat.

In this case, the cooling could also be done with air as a heat transfer medium. A purely convection cooling would also be possible in this case. In this case, additional openings can be provided on the structure.

Advantageous configurations and embodiments result from the further subordinate claims and from the description with reference to the figures of the drawings.

According to an advantageous embodiment, a transparent region is provided between and/or close to the solar cells, wherein the first section of the structure in the transparent region at least partially reflects the incidental light on the rear-side of the solar cells. Thus, the electrical efficiency of the solar module is increased.

According to a preferred embodiment, the first section of the structure is disposed spaced apart from the laminate rear-side. Advantageously, an enlarged gap is thus provided between the reflecting surface and the rear-side rear-side of the at least partially bifacial solar cells. This can be utilized for deflecting a larger proportion of the reflected light on the solar cell rear-side.

According to an advantageous embodiment, the first section of the structure extends parallel to the laminate rear-side. Thus, the light can be reflected in a particularly simple way by means of a scattering or diffuse reflector on larger and/or several solar cell rear-sides.

According to a more advantageous embodiment, a second section of the structure is provided, which is disposed in a region covered by the solar cells. This can be configured, for example, for the purpose of mechanically supporting the laminate.

According to a preferred embodiment, the second section of the structure is provided with a thermal contact with the laminate rear-side. The laminate and thereby, even the solar cells can thus be cooled by means of the structure conducting the heat transfer medium. For example, an intensive thermal coupling can be made by means of a heat conduction paste. Therefore, the material of the second section of the structure is configured and provided as a conductor, to transfer the heat energy dissipated from the laminate to the heat transfer medium.

According to an advantageous embodiment, the structure is at least partially formed with a cap profile. Advantageously, thus the structure is to be made easily by means of a cap profile. For example, the cap profile can be formed from profiled and/or welded sheets. A configuration out of a continuous multiple folded sheet is also possible. In addition, the cap profile can be used as the structural base of the solar module. Thus, another support structure or a frame of the solar module can be dimensioned smaller or eliminated.

In an embodiment, the structure has a fluid channel partially confined by the cap profile. Therefore, the fluid channel is preferably used for conducting the heat transfer medium. Alternatively or additionally, the fluid channel can be filled with a transparent liquid, such as Silicon or EVA (Ethylene vinyl acetate). In case of several fluid channels, individual channels therefrom can be filled with a transparent liquid. Further, the fluid channel or individual fluid channels can alternatively or additionally also be used as opening for convection cooling of the solar module.

According to an embodiment, a first plane of the cap profile forms the first section of the structure and a second plane of the cap profile which extends parallel to the first plane, at least partially forms the second section of the structure. Thus, automatically the first section of the structure is advantageously spaced apart from the laminate rear-side.

According to an embodiment, the second section of the structure is configured as solar hot water collector element. According to this, it can be provided partially without a reflecting surface, particularly on the sections other than the first section. Optionally or additionally, the collector element can have an absorption promoting surface. In addition, the collector element can be formed with an enlarged surface, for example as a flat element to provide an improved heat transfer.

According to another embodiment, the first section of the structure is formed with a rear plate extending parallel to the laminate rear-side. Therefore, a fluid channel is confined by the rear plate and by the laminate rear-side. For example, the rear plate can be formed from the glass. For confinement from the sides, additional sealing elements can be provided. In this case, the rear plate can describe a lower limiting surface of the fluid channel, which then have the reflecting surface, at least partially in the first section of the structure.

According to an embodiment, a groove is introduced in the rear plate, which forms the fluid channel. In particular, several grooves can be introduced, which form a fluid channel each. Thus, fluid channel is or fluid channels are formed in the rear plate itself. Thus, the expenditure for sealing the solar module is advantageously distinctly reduced. Further, few individual components are thus necessary advantageously.

According to an alternative embodiment, spacers are provided between the laminate rear-side and the rear plate, which define the gap between these. Advantageously, the stability and dimensional tolerance of the solar module can be ensured in this way, even in large surfaces which are usually formed with glass panes.

According to an advantageous embodiment, the spacers are configured as sealing and/or heat conduction elements. Preferably, these therefore confine the fluid channel between the laminate rear-side and the rear plate. Thus, a defined fluid channel is advantageously formed with lower expenditure. In particular, the first section of the structure can thus be separated from the fluid channel in a simple way.

According to an embodiment, the fluid channel extends through the region respectively covered by the solar cells. Thus, the region in which the first section of the structure reflects light on the solar cells, is advantageously not impaired. Further, an excellent heat transfer of waste heat from the solar cell is thus ensured advantageously.

According to an advantageous embodiment, the structure includes pipes configured for conducting the heat transfer medium. These particularly have a suitable sealing and chemical stability for conducting a heat transfer medium.

According to an embodiment, the pipes are provided in an encapsulation bordering the laminate rear-side. Optionally or additionally, connections of the pipes can be provided for a subsequent piping for the heat transfer medium into the encapsulation by injection. Advantageously, such an integral and simple implementation of the piping to be made is easily provided.

In an embodiment, the encapsulation is formed with a foamed white plastic. In this case, the encapsulation itself, at least partially forms the first section of the structure. Plastic foams are advantageously light, mechanically stable and very cost-effective. Further, such a configuration offers the possibility to simultaneously use the foamed plastic as roof-insulation material, particularly for heat/cold insulation in the so-called In-roof modules.

The foamed white plastic can include polyurethane hard foam or polystyrol foam.

Preferably, the foamed white plastic of the encapsulation is configured as diffuse reflector on the side thereof facing the laminate rear-side. Thus, the configuration of the structure along with pipes and reflector is realized in a very cost-effective manner. For adjusting, particularly increasing the reflection factor, if necessary, pigments, particularly white pigments can be blended in the foamed white plastic. Alternatively or additionally, an already virgin highly reflective foamed white plastic can be used. In particular, it can therefore include polystyrol foam, which has an already high reflection factor of >90% even without pigment addition.

According to another embodiment, the encapsulation is configured transparent. In this case, the pipes at least partially form the first section of the structure. Therefore, the encapsulation is used for the mechanical stability of the structure.

In particular, therefore the pipes are configured with a reflecting surface on the sides thereof facing the laminate rear-side. For example, the pipes can be provided as pipes with reflecting surface, embedded in the encapsulation.

In addition, the pipes are preferably configured round, wherein the reflecting surface of the pipes is oriented in different directions, corresponding to the round configuration.

According to an embodiment, the pipes are configured as hollow cavities in the encapsulation. In particular, the pipes formed integrally with the encapsulation conduct air as heat transfer medium and accordingly perfused with air. In case of a transparent encapsulation, the pipes can be configured as hollow cavities with reflecting wall. For this purpose, the boundary layer to the hollow cavity is designed accordingly. This can be done by a corresponding processing. It is also possible to coat the hollow cavities with a reflecting material.

The above configurations and embodiments can be freely combined with each other, where appropriate. Further possible configurations, embodiments and implementations of the invention also include the combinations not explicitly mentioned from the features of the invention described previously or in the following with reference to the exemplary embodiments. In particular, therefore, the skilled person will also add individual aspects as improvements or modifications to the respective basic form of the present invention.

### SUMMARY OF THE DRAWING

The present invention is explained in the following with the help of the exemplary embodiments indicated in the schematic figures of the drawing. There are:

FIG. 1 showing a schematic cross-sectional view of a solar module according to a first exemplary embodiment;

FIG. 2 showing a schematic cross-sectional view of a solar module according to a second exemplary embodiment;

FIG. 3 showing a schematic cross-sectional view of a solar module according to a third exemplary embodiment;

FIG. 4 showing a schematic cross-sectional view of a solar module according to a fourth exemplary embodiment;

FIG. 5 showing a schematic cross-sectional view of a solar module according to a fifth exemplary embodiment;

FIG. 6 showing a schematic cross-sectional view of a solar module according to a sixth exemplary embodiment;

FIG. 7 showing a schematic cross-sectional view of a solar module according to a seventh exemplary embodiment;

FIG. 8 showing a schematic cross-sectional view of a solar module according to an eighth exemplary embodiment;

FIG. 9 showing a schematic cross-sectional view of a solar module according to a ninth exemplary embodiment; and

FIG. 10 showing a schematic cross-sectional view of a solar module according to a tenth exemplary embodiment.

The accompanying figures of the drawing should impart a further understanding of the embodiments of the invention. These illustrate the embodiments and are used in conjunction with the description of the explanation of the principles and concepts of the invention. Other embodiments and many of the cited advantages result in view of the drawings. The elements of the drawings are not necessarily shown to scale with respect to each other.

In the figures of the drawing, the same, functionally similar elements, features and components and having the same effect are provided with the same reference numerals, unless stated otherwise.

### DESCRIPTION OF EXEMPLARY EMBODIMENTS

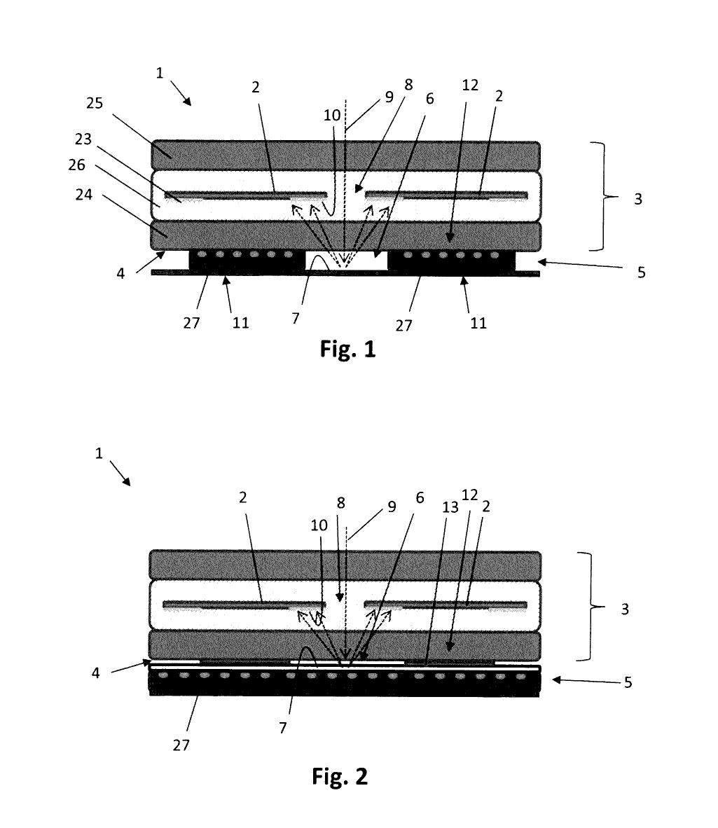

FIG. 1 shows a schematic cross-sectional view of a solar module 1 according to a first exemplary embodiment.

The solar module 1 shown includes a hybrid photovoltaic solar hot water module.

This has two adjoining solar cells 2, which respectively have a rear-side 10 and are configured partially bifacial. Here, two solar cells 2 are shown merely by way of example. Any other number of solar cells can also be provided.

In particular, this includes edge bifacial solar cells, which have an edge area 23 configured bifacial.

An example for the construction of such edge bifacial solar cells is described in the German utility model DE 20 2015 102 238 U1.

The solar cells are embedded in a transparent laminate 3. The transparent laminate 3 has an upper and a lower cover plate and an intermediate transparent encapsulating material 26, in which the solar cells 2 are disposed. The cover plates 24, 25 are preferably made of glass.

A transparent region 8 of the laminate 3 is provided between both the solar cells 2.

The laminate 3 has a laminate rear-side 4, on which structure 5 configured for conducting a heat transfer medium, is provided.

The structure 5 has a first section 6 and a second section 11. The first section 6 is configured with a reflecting surface 7 facing the laminate rear-side 4. The exemplary embodiment represented includes a diffuse reflecting surface. For example, it can therefore include a white coated sheet, for example having an Albedo of at least 50%, preferably at least 80%.

Further, the first section is disposed under the transparent region 8, so that light 9 on the solar module 1 incident in the region of the transparent section 8 impinges on the first section and is reflected to a large part on the reflecting surface 7 on the rear-side 10 of the solar cells 2, predominantly in the bifacial edge regions 23.

A transparent region can also be provided on the edge of the solar module 1. In this case, an additional first section of the structure 5 having a reflecting surface 7 can also be provided at the edge of the solar module.

The second section 11 is respectively formed with a solar hot water collector element 27 and is disposed in a region 12 covered by the solar cells 2. Therefore, the solar hot water collector element 27 is in direct contact with the laminate rear-side 4, so that a heat transfer is made possible from the laminate 3 to the solar hot water collector element 27. Optionally, a thermal contact, not represented here, for example in the form of a heat conduction paste which thermally couples the laminate rear-side 4 with the solar hot water collector element 27, can be provided for this purpose.

The solar hot water collector element 27 exemplarily includes a block provided with holes for a heat transfer fluid, which has excellent heat transfer properties. Thus, the heat transfer medium conducted in the holes can dissipate heat energy absorbed on the collector element 27. The block can be made of, for example, Aluminum or Copper.

Thus, the collector element 27 cools the solar cells 2. Therefore, the solar cells 2 can be maintained in a low-temperature range, in which these show a higher efficiency. For example, the solar cells are maintained in a temperature range below 40° C., preferably in the range of 20° C. to 30° C. Thus, under solar exposure, a constant heat conduction takes place from the solar cells 2 via the laminate 3 and the laminate rear-side 4 to the collector element 27 and finally to the heat transfer medium.

In addition, the collector element 27 includes an external coating and/or color in the regions 12 covered by the solar cells 2, which show a high absorption coefficient. Thus, the solar radiations not captured in the solar cells 2 or repeatedly scattered radiations are absorbed and dissipated as useful heat energy.

In the following, further exemplary embodiments are explained, wherein merely the differences from the first exemplary embodiment are discussed. Therefore, the elements not explicitly described are functionally identical to the first exemplary embodiment.

FIG. 2 shows a schematic cross-sectional view of a solar module 1 according to a second exemplary embodiment.

In contrast to the first exemplary embodiment, the structure 5 according to this second exemplary embodiment includes a solar hot water collector element 27, which extends over the entire surface of the solar module 1.

As a further difference, the reflecting surface 7 is disposed between the laminate rear-side 4 and the collector element 27. Purely exemplarily, here the reflecting surface 7 likewise extends over the entire surface of the solar module 1. Likewise, it is also possible to provide an extension of the reflecting surface 7 only close to the transparent regions 8.

Thermal contacts 13 are provided between the collector element 27 and the laminate rear-side 4, which thermally couple the laminate with the structure 5.

Preferably, these thermal contacts 13 are disposed, as represented here, in the regions 12 covered by the solar cells 2. For example, the thermal contacts 13 can include heat conducting paste.

Purely exemplarily, the thermal contacts 13 are applied on the reflecting surface 7. Likewise, the reflecting surface 7 can however be interrupted or excluded in the regions 12 covered by the solar cells, so that the thermal contact 13 directly thermally couples the laminate rear-side 4 with the collector element 27.

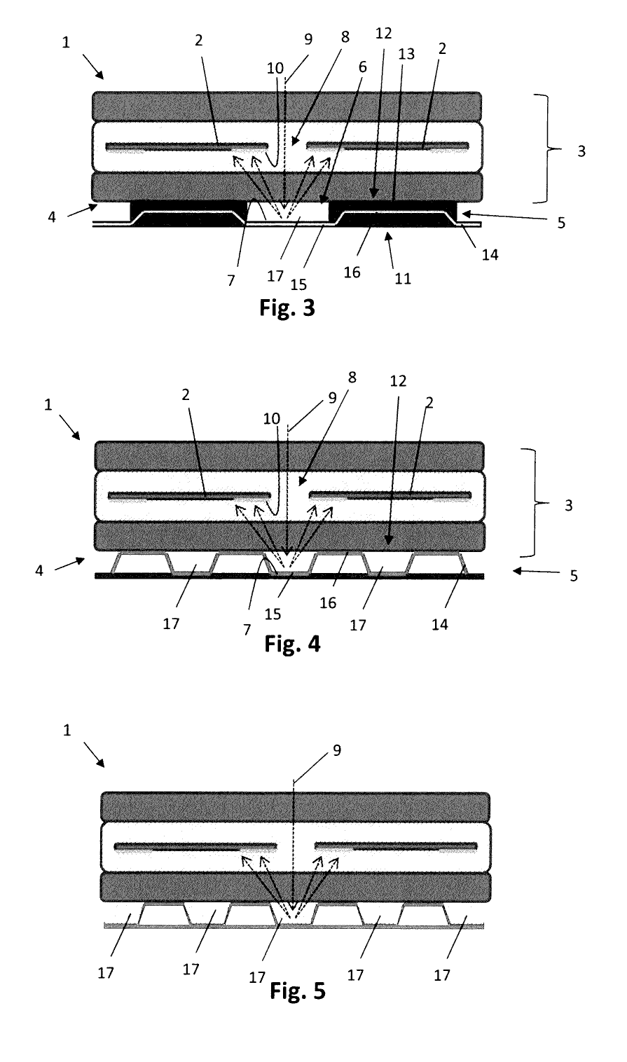

FIG. 3 shows a schematic cross-sectional view of a solar module according to a third exemplary embodiment.

In contrast to the preceding exemplary embodiment, here the structure 5 is configured with a cap profile 14. In particular, the cap profile 14 includes a continuous sheet, which has a plurality of recurring cap shapes provided juxtaposed in the cross-section.

The cap profile 14 has a first plane 15, which forms the first section 6 of the structure 5. Further, a second plane 16 is provided, which forms the second section 11 of the structure 5.

A thermal contact 13 is provided in the region of the second section 11, which thermally couples the cap profile 14 of the structure 5 with the laminate rear-side 4.

In the first section 6, the first plane 15 of the profile 5 is spaced apart from the laminate rear-side 4 and provided with the reflecting surface 7.

Thus, a fluid channel 17 is formed between the laminate rear-side 4 and the reflecting surface 7, which can conduct a heat transfer medium. The heat transfer to a heat transfer medium can take place here on the first plane 15 of the cap profile 14. Further, the heat transfer from the thermal contact 13 to the heat transfer medium can also take place laterally.

For example, the fluid channel 17 can be used as an opening for a convection cooling and therefore, can conduct air as a heat transfer medium. However, a liquid can also be conducted in the fluid channel 17 as a heat transfer medium.

FIG. 4 shows a schematic cross-sectional view of a solar module according to a fourth exemplary embodiment.

Here, the structure 5 is likewise formed with a cap profile 14, wherein additional fluid channels 17 are provided in the respective region 12 covered by the solar cells 2.

In the region 12 covered by the solar cells 2, accordingly the second plane 16 of the profile is interrupted with an additional section of the first plane 15 for forming a fluid channel.

Thus, it is made possible to cool the laminate 3 or the solar cells 2 in the regions 12 covered by the solar cells 2 through a direct contact with the laminate rear-side 4 by a heat transfer medium, which can be conducted in the fluid channel 17.

FIG. 5 shows a schematic cross-sectional view of a solar module 1 according to a fifth exemplary embodiment.

This exemplary embodiment substantially corresponds to the fourth exemplary embodiment according to FIG. 4, wherein additionally a transparent liquid is provided in the fluid channels 17 here. For example, this transparent liquid can be a heat transfer fluid conducted in the structure.

It would also be possible to at least partially provide a transparent liquid of Silicon or EVA (Ethylene vinyl acetate) in the fluid channels 17. This can be used optionally or additionally for sealing the solar module. In this case, it can also include a solid transparent filling.

Therefore, if all fluid channels 17 directly adjoining the laminate rear-side are filled with a solid transparent filling, the channels of the profile not directly in contact with the laminate rear-side contact, parallel offset thereto, can nevertheless be used for conducting the heat transfer medium.

Further, it would be possible to provide, only close to the transparent region 8, a solid transparent filling in the first section of the structure for ensuring the desired reflection characteristics, for example with a desired refractive index. Therefore, the heat transfer medium can be conducted in the region 12 covered by the solar cells 2 however for cooling or for heat exchange.

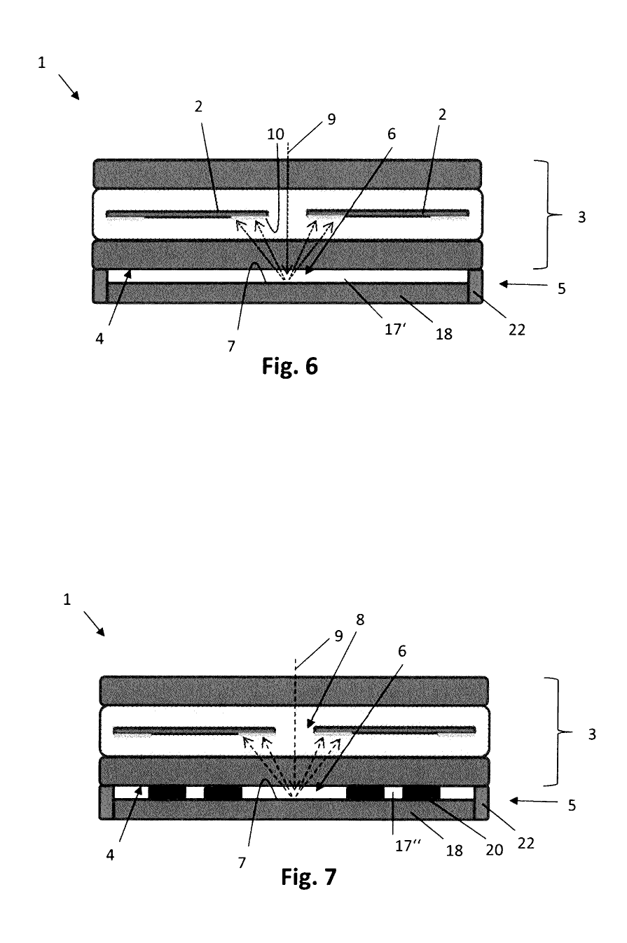

FIG. 6 shows a schematic cross-sectional view of a solar module 1 according to a sixth exemplary embodiment.

In contrast to the preceding exemplary embodiments, here the structure 5 is formed with a rear plate 18 extending parallel to the laminate rear-side 4.

The surface of the rear plate 18 simultaneously forms here the reflecting surface 7. Preferably, the rear plate 18 is made of glass.

A fluid channel 17′ is confined by the laminate rear-side 4 and the rear plate 18. In addition, the fluid channel is confined by lateral seals 22. Thus, a fluid channel 17′ is formed, which extends over a large surface of the solar module 1.

FIG. 7 shows a schematic cross-sectional view of a solar module 1 according to a seventh exemplary embodiment.

In contrast to the sixth exemplary embodiment according to FIG. 6, here additional spacers 20 are provided, which are disposed between the laminate rear-side 4 and the rear plate 18. The spacers 20 define and maintain the predetermined distance between the laminate rear-side 4 and the rear plate 18.

Further, the spacers 20 are configured here as sealing element and confine the fluid channels 17″ located between the laminate rear-side 4 and the rear plate 18.

Alternatively, the spacers 20 can also be provided only locally and can merely be used as mechanical supports, therefore without confining the fluid channels.

In addition, the spacers 20 can be optionally or additionally configured as heat conduction elements to provide an enlarged surface which is in contact with the heat transfer medium conducted in the fluid channel 17″.

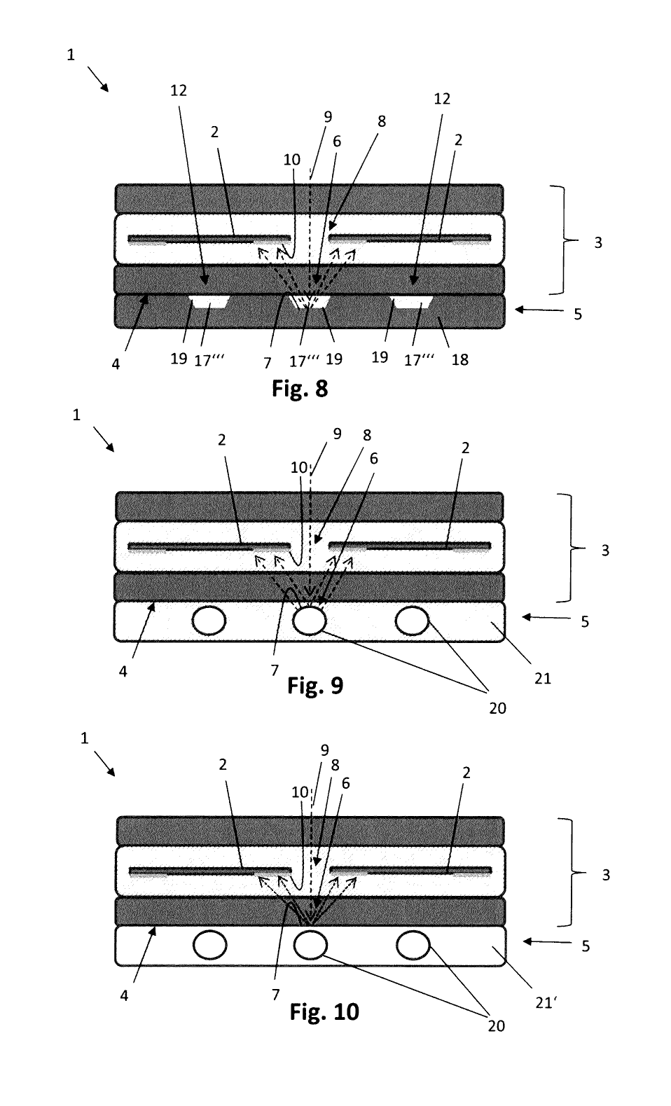

FIG. 8 shows a schematic cross-sectional view of a solar module according to an eighth exemplary embodiment.

In contrast to the sixth and seventh exemplary embodiments, the rear plate 18 is directly supported on the laminate rear-side 4.

Grooves 19 are introduced in the rear plate 18 for forming fluid channels 17″′.

Therefore, a groove 19 disposed close to the transparent region 8 forms the first section 6 of the structure 5 and is provided with a reflecting surface 7 on the groove base thereof.

Additional grooves 19 are provided further in the second section 11 of the structure 5.

A transparent liquid is provided in the grooves 19 or fluid channels 17″′. Therefore, preferably the heat transfer medium is in the form of a heat transfer fluid.

Thus, a heat transfer medium is conducted in the region 12 covered by the solar cells 2 for cooling the solar cells 2 or for heat exchange in the fluid channels 17″′.

If the heat transfer medium is fully transparent, the first section 6 of the structure 5 can also be used for conducting the heat transfer medium.

In another configuration, it would be possible to provide a solid transparent filling of the groove 19 in the first section 6 of the structure 5 close to the transparent region 8 as an alternative, for ensuring the desired reflection characteristics, for example, with a desired refraction index.

FIG. 9 shows a schematic cross-sectional view of a solar module according to a ninth exemplary embodiment.

In contrast to the preceding exemplary embodiments, here the structure 5 includes pipes 20, which are provided in a transparent encapsulation 21. In particular, the pipes 20 are provided embedded in the transparent encapsulation 21.

The transparent encapsulation 21 directly borders the laminate rear-side 4.

The pipes 20 are round and configured for conducting a heat transfer medium. Therefore, a pipe 20 disposed after the transparent region 8 of the laminate 3 is configured as first section 6 of the structure 5 and has a reflecting surface 7 for this purpose.

Based on the curvature of the reflecting surface 7, the incidental light 9 thereon is reflected in different directions. Here, it can particularly involve total reflection, since the curved reflecting surface 7 already provides the scattering of the reflected light 9.

FIG. 10 shows a schematic cross-sectional view of a solar module according to a tenth exemplary embodiment.

Here, the structure 5 is formed with an encapsulation 21′, which is formed with a foamed white plastic. For example, it includes polyurethane hard foam or polystyrol foam. Thus, the encapsulation 21′ here is formed non-transparent and itself forms the first section 6 of the structure close to the transparent region 8 of the laminate 3.

Therefore, the reflecting surface 7 is likewise formed by the encapsulation itself, which provides a high reflection factor, particularly too diffuse reflection based on the white color thereof. For example, such a reflection factor is above 50%, preferably above 80%. For adjustment, particularly for increasing the reflection factor, pigments can be blended in the foamed white plastic, where appropriate. Alternatively, an already virgin highly reflecting foamed white plastic can be used. Therefore, it can particularly include polystyrol foam, which already has a high reflection factor of >90% even without pigment addition.

The pipes 20 can be provided either embedded in the encapsulation 21′ or directly formed with the encapsulation 21′ itself.

In case of pipes 20 directly formed with the encapsulation, these preferably conduct air as a heat transfer medium and are accordingly perfused with air.

Although, the present invention was completely described above with the help of preferred exemplary embodiments, it is not restricted to these, but can be modified in many different ways.

For example, connections can be provided for a subsequent piping for injecting with the heat transfer medium into the encapsulation.

Further, in case of a structure formed with a foamed white plastic, the solar module can simultaneously be used as roof-insulation material, particularly for heat/cold insulation. This is particularly advantageous in the so-called in-roof solutions of a solar module, wherein the solar module replaces the roof covering.

### LIST OF REFERENCE NUMERALS

1 Solar module
2 Solar cell
3 Laminate
4 Laminate rear-side
5 Structure
6 First section
7 Reflecting surface
8 Transparent region
9 Light
10 Rear-side
11 Second section
12 Covered area
13 Thermal contact
14 Cap profile
15 First plane
16 Second plane
17-17″′ Fluid channel
18 Rear plate
19 Groove
20 Spacer
21; 21′ Encapsulation
22 Side seal
23 Periphery
24; 25 Cover plate
26 Encapsulating material
27 Collector element

1. Solar module,
having at least two adjoining solar cells, which are configured at least partially bifacial and are embedded into a transparent laminate,
wherein the laminate has a laminate rear-side on which a structure for guiding a heat transfer medium is provided,
wherein a first section of the structure facing the laminate rear-side has a reflecting surface and is disposed to reflect the incidental light on the solar module, which does not directly strike the solar cells.

2. Solar module according to claim 1, wherein,
a transparent region is provided between and/or close to the solar cells, wherein the first section of the structure in the transparent region at least partially reflects the incidental light on the rear-side of the solar cells.

3. Solar module according to claim 2, wherein,
the first section of the structure is disposed spaced apart from the laminate rear-side.

4. Solar module according claim to 3, wherein,
the first section of the structure extends parallel to the laminate rear-side.

5. Solar module according to one claim 4, wherein,
a second section of the structure is provided, which is disposed in a region covered by the solar cells.

6. Solar module according to claim 5, wherein,
the second section of the structure is provided with a thermal contact with the laminate rear-side.

7. Solar module according to claim 6, wherein,
the structure is at least partially formed with a cap profile.

8. Solar module according to claim 7, wherein,
the structure has a fluid channel at least partially confined by the cap profile.

9. Solar module according to claim 8, wherein,
a first plane of the cap profile forms the first section of the structure and a second plane of the cap profile which extends parallel to the first plane, at least partially forms the second section of the structure.

10. Solar module according to claim 5, wherein,
at least the second section of the structure is configured as solar hot water collector element.

11. Solar module according to claim 3, wherein,
the first section of the structure is formed with a rear-plate extending parallel to the laminate rear-side, wherein the fluid channel is confined by the rear-plate and by the laminate rear-side.

12. Solar module according to claim 11, wherein,
a groove is introduced in the rear-plate, which forms the fluid channel, which form a fluid channel each.

13. Solar module according to claim 11, wherein,
spacers are provided between the laminate rear-side and the rear-plate, which define the gap between these.

14. Solar module according to claim 13, wherein,
the spacers are configured as sealing and/or heat conduction elements and confine the fluid channel between the laminate rear-side and the rear-plate.

15. Solar module according to claim 7, wherein,
the fluid channel extends through a region respectively covered by the solar cells.

16. Solar module according to claim 1, wherein,
the structure comprises pipes configured for guiding the heat transfer medium.

17. Solar module according to claim 16, wherein,
the pipes are provided in an encapsulation bordering the laminate rear-side.

18. Solar module according to claim 17, wherein,
the encapsulation is formed with a foamed white plastic and at least partially forms the first section of the structure.

19. Solar module according to claim 18, wherein,
the foamed white plastic of the encapsulation is configured as diffuse reflector on the side thereof facing the laminate rear-side.

20. Solar module according to claim 17, wherein,
the encapsulation is configured transparent and the pipes at least partially form the first section of the structure.
